(19) United States
(12) Patent Application Publication
(10) Pub. No.: US 2021/0066099 A1
(43) Pub. Date: Mar. 4, 2021

(54) APPARATUS AND METHOD FOR PROCESSING SUBSTRATE

(71) Applicant: SEMES CO., LTD., Cheonan-si (KR)

(72) Inventors: Muhyeon LEE, Cheonan-si (KR); Byungsun BANG, Hwaseong-si (KR); Heehwan KIM, Sejong-si (KR)

(73) Assignee: SEMES CO., LTD., Cheonan-si (KR)

(21) Appl. No.: 17/011,048

(22) Filed: Sep. 3, 2020

(30) Foreign Application Priority Data
Sep. 4, 2019 (KR) 10-2019-0109579

(51) Int. Cl. H01L 21/67; H01L 21/687; H01L 21/02; B08B 3/10

(52) U.S. Cl. CPC H01L 21/67051; B08B 3/10; H01L 21/02057; H01L 21/68764

(57) ABSTRACT

A method for processing a substrate includes a liquid treatment step of performing liquid treatment on the substrate by dispensing a treatment liquid onto the rotating substrate and a cleaning step of stopping the dispensing of the treatment liquid and dispensing a cleaning solution onto the substrate. In the cleaning step, a first liquid is dispensed from a first nozzle above the rotating substrate to a point spaced apart from the center of the substrate in a first direction, and a second liquid is dispensed from a second nozzle above the rotating substrate to a point spaced apart from the center of the substrate in a second direction. When viewed from above, the first liquid flows toward the second nozzle after dispensed onto the substrate, and the second liquid flows toward the first nozzle after dispensed onto the substrate.

### CROSS-REFERENCE TO RELATED APPLICATIONS

A claim for priority under 35 U.S.C. § 119 is made to Korean Patent Application No. 10-2019-0109579 filed on Sep. 4, 2019, in the Korean Intellectual Property Office, the entire contents of which are hereby incorporated by reference.

### BACKGROUND

Embodiments of the inventive concept described herein relate to an apparatus and method for processing a substrate, and more particularly, relate to a substrate processing apparatus and method for performing liquid treatment on a substrate by dispensing a liquid onto the substrate.

Various processes, such as photolithography, deposition, ashing, etching, ion implantation, and the like, are performed to manufacture semiconductor elements. Before and after these processes, a cleaning process is performed to remove particles remaining on a substrate.

The cleaning process includes a process of dispensing a chemical onto the rotating substrate supported on a spin head, a process of removing the chemical on the substrate by dispensing a cleaning solution such as deionized water (DIW) onto the substrate, a process of replacing the cleaning solution on the substrate with an organic solvent by dispensing the organic solvent such as isopropyl alcohol (IPA), the surface tension of which is lower than that of the cleaning solution, onto the substrate, and a process of removing the organic solvent from the substrate. In the cleaning process, to prevent the substrate from being dried, deionized water is dispensed onto the substrate before and after the dispensing of the chemical.

The cleaning process is performed by dispensing various liquids onto the substrate, which rotates in a cup in which the substrate is processed, through nozzles. The nozzles move between process positions and standby positions. The process positions are positions in which the nozzles are located above the substrate to perform liquid treatment on the substrate. The standby positions are positions in which nozzles not performing liquid treatment on the substrate stand by so as not to hamper a nozzle performing liquid treatment on the substrate.

When a nozzle having dispensed a liquid moves from a process position to a standby position and then a nozzle for dispensing another liquid moves from a standby position to a process position, nozzles fixed to the cup dispense deionized water onto the substrate W to prevent the substrate W from being naturally dried. Alternatively, the nozzles fixed to the cup dispense deionized water onto the substrate to remove the chemical on the substrate after the substrate is processed by the chemical.

In the related art, as illustrated in FIG. 1, two nozzles 21 and 23 dispense deionized water onto a center region P1 and a middle region P2 of a rotating substrate W. As the deionized water dispensed onto the center region P1 and the deionized water dispensed onto the middle region P2 flow in the same direction by the rotation of the substrate W, the deionized water dispensed onto the center region P1 collides with the deionized water dispensed onto the middle region P2, while flowing toward an edge region of the substrate W. The rotational kinetic energy of the deionized water dispensed onto the center region P1 is increased as the deionized water dispensed onto the center region P1 flows toward the edge region of the substrate W, and therefore the deionized water dispensed onto the middle region P2 is thrown out toward the outside of the substrate W by the collision.

Due to this, a partial region of the substrate W may be dried without being wetted. Furthermore, the level of the deionized water thrown out by the collision may be raised, and as illustrated in FIG. 2, the deionized water may be scattered to the outside of the substrate W after colliding with chuck pins 10 that support the side of the substrate W.

Because the deionized water contains a chemical in a process of replacing the chemical, the scattered deionized water may contaminate the inside of a chamber, and the deionized water rebounded from a bowl may adhere to the substrate W again.

### SUMMARY

Embodiments of the inventive concept provide a substrate processing apparatus and method for improving substrate cleaning efficiency.

Embodiments of the inventive concept provide a substrate processing apparatus and method for preventing collision of deionized water dispensed to different positions on a substrate.

Embodiments of the inventive concept provide a substrate processing apparatus and method for preventing a chamber or parts therein from being contaminated by a cleaning solution dispensed onto a substrate.

The technical problems to be solved by the inventive concept are not limited to the aforementioned problems, and any other technical problems not mentioned herein will be clearly understood from the following description by those skilled in the art to which the inventive concept pertains.

According to an exemplary embodiment, a method for processing a substrate includes a liquid treatment step of performing liquid treatment on the substrate by dispensing a treatment liquid onto the rotating substrate and a cleaning step of stopping the dispensing of the treatment liquid and dispensing a cleaning solution onto the substrate. In the cleaning step, a first liquid is dispensed from a first nozzle above the rotating substrate to a point spaced apart from the center of the substrate in a first direction, and a second liquid is dispensed from a second nozzle above the rotating substrate to a point spaced apart from the center of the substrate in a second direction. When viewed from above, the first liquid flows toward the second nozzle after dispensed onto the substrate, and the second liquid flows toward the first nozzle after dispensed onto the substrate.

According to an embodiment, the first liquid and the second liquid may be dispensed in oblique directions with respect to the substrate.

According to an embodiment, when viewed from above, the first liquid and the second liquid may be dispensed in opposite directions toward each other.

According to an embodiment, the point to which the first liquid is dispensed and the point to which the second liquid is dispensed may be spaced apart from each other by a predetermined distance in opposite directions from the center of the substrate.

According to an embodiment, the substrate may have a diameter of 300 mm, and the point to which the first liquid is dispensed and the point to which the second liquid is dispensed may be spaced apart from each other by a distance of 5 mm to 30 mm.

According to an embodiment, the first nozzle and the second nozzle may be fixed to a cup that surrounds a processing space in which the substrate is processed.

According to an embodiment, the first liquid and the second liquid may be simultaneously dispensed.

According to an embodiment, the first liquid and the second liquid may be of the same type.

According to an exemplary embodiment, an apparatus for processing a substrate includes a housing having a processing space therein, a support unit that supports the substrate in the processing space, a first nozzle that dispenses a first liquid to a first point on a target surface of the substrate supported on the support unit, and a second nozzle that dispenses a second liquid to a second point on the target surface of the substrate supported on the support unit. When viewed from above, the first point is located on one side of a virtual line connecting a dispensing end of the first nozzle and a dispensing end of the second nozzle, and the second point is located on an opposite side of the virtual line.

According to an embodiment, the center of the substrate may be located between the first point and the second point.

According to an embodiment, a distance between the first point and the center of the substrate may be equal to a distance between the second point and the center of the substrate.

According to an embodiment, when viewed from above, the first nozzle and the second nozzle may be provided in opposite directions toward each other.

According to an embodiment, the first nozzle may dispense the first liquid to the first point spaced apart from the center of the substrate by a first distance, and the second nozzle may dispense the second liquid to the second point spaced apart from the center of the substrate by a second distance in a direction away from the first point with respect to the center of the substrate.

According to an embodiment, the first distance may be equal to the second distance.

According to an embodiment, the substrate may have a diameter of 300 mm, and the point to which the first liquid is dispensed and the point to which the second liquid is dispensed may be spaced apart from each other by a distance of 5 mm to 30 mm.

According to an embodiment, the apparatus may further include a cup that surrounds the processing space, and the first nozzle and the second nozzle may be fixed to the cup.

According to an embodiment, the first liquid and the second liquid may be the same as each other.

According to an exemplary embodiment, a method for processing a substrate includes simultaneously dispensing a first liquid and a second liquid onto the substrate from a first nozzle and a second nozzle in oblique directions from above the rotating substrate, and the direction in which the first liquid is dispensed from the first nozzle and the direction in which the second liquid is dispensed from the second nozzle differ from each other such that the first liquid dispensed from the first nozzle and the second liquid dispensed from the second nozzle are spread in different directions by the rotation of the substrate.

According to an embodiment, when viewed from above, the direction in which the first liquid is dispensed and the direction in which the second liquid is dispensed may form 180 degrees therebetween.

According to an embodiment, a point to which the first liquid is dispensed and a point to which the second liquid is dispensed may be spaced apart from each other by a predetermined distance in opposite directions from the center of the substrate.

According to an embodiment, the first nozzle and the second nozzle may be fixed to a cup that surrounds a processing space in which the substrate is processed.

According to an embodiment, the first liquid and the second liquid may be of the same type.

According to an embodiment, a third nozzle may dispense a third liquid onto the substrate in an oblique direction from above the rotating substrate.

According to an embodiment, the direction in which the first liquid is dispensed, the direction in which the second liquid is dispensed, and the direction in which the third liquid is dispensed may form 120 degrees therebetween.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a state in which a cleaning solution is dispensed onto a substrate in a substrate processing apparatus in the related art;

FIG. 2 is a view illustrating a state in which the cleaning solution collides with a chuck pin and scatters outside the substrate in the substrate processing apparatus in the related art;

FIG. 3 is a schematic plan view illustrating a substrate processing apparatus according to an embodiment of the inventive concept;

FIG. 4 is a schematic view illustrating one embodiment of liquid treatment chambers of FIG. 3;

FIG. 5 is a top view illustrating a first nozzle and a second nozzle according to an embodiment of the inventive concept;

FIG. 6 is a view illustrating a state in which a first liquid and a second liquid are dispensed onto a rotating substrate; and

FIG. 7 is a top view illustrating a first nozzle, a second nozzle, and a third nozzle according to an embodiment of the inventive concept.

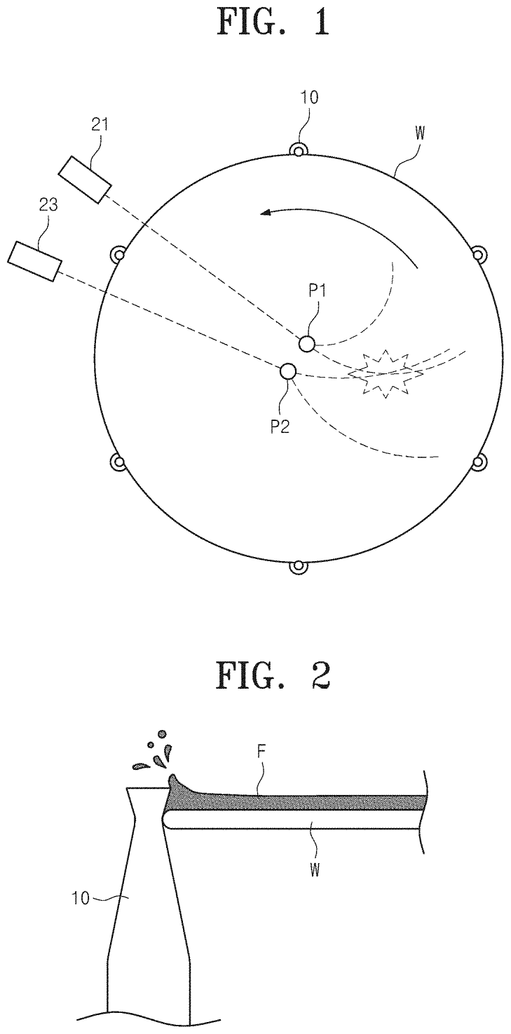

### DETAILED DESCRIPTION

Hereinafter, embodiments of the inventive concept will be described in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. In the drawings, the dimensions of components are exaggerated for clarity of illustration.

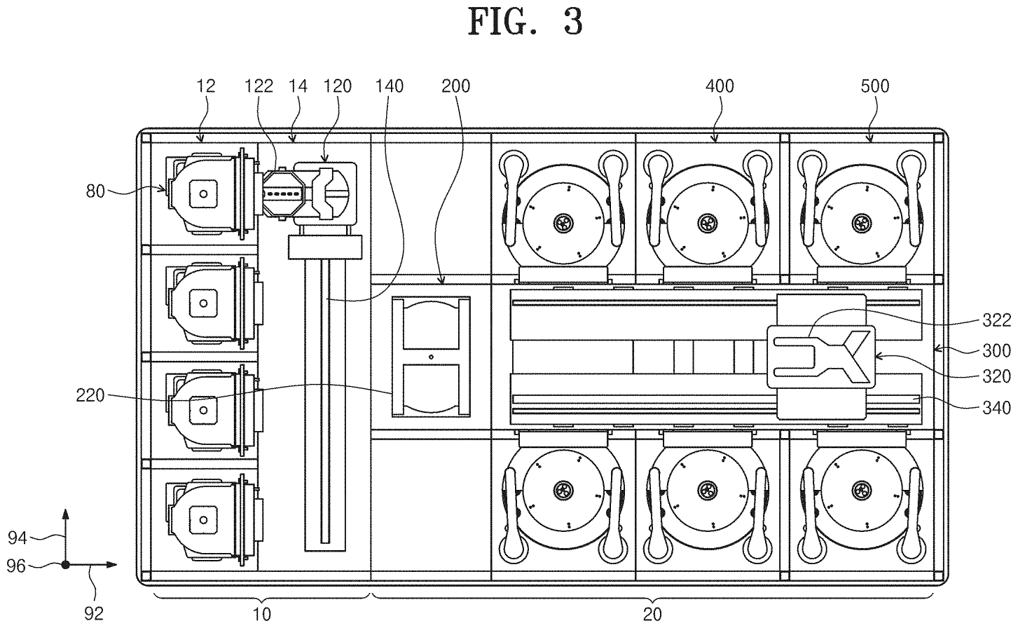

FIG. 3 is a schematic plan view illustrating a substrate processing apparatus according to an embodiment of the inventive concept.

Referring to FIG. 3, the substrate processing apparatus includes an index module 10 and a process module 20. According to an embodiment, the index module 10 and the process module 20 are disposed along one direction. Hereinafter, the direction in which the index module 10 and the process module 20 are disposed is referred to as a first direction 92, a direction perpendicular to the first direction 92 when viewed from above is referred to as a second direction 94, and a direction perpendicular to both the first direction 92 and the second direction 94 is referred to as a third direction 96.

The index module 10 transfers substrates W from carriers 80 to the process module 20 and places, in the carriers 80, the substrates W completely processed in the process module 20. The lengthwise direction of the index module 10 is parallel to the second direction 94. The index module 10 has load ports 12 and an index frame 14. The load ports 12 are located on the opposite side to the process module 20 with respect to the index frame 14. The carriers 80, each of which has the substrates W received therein, are placed on the load ports 12. The load ports 12 may be disposed along the second direction 94.

Airtight carriers, such as front open unified pods (FOUPs), may be used as the carriers 80. The carriers 80 may be placed on the load ports 12 by a transfer unit (not illustrated) such as an overhead transfer, an overhead conveyor, or an automatic guided vehicle, or by an operator.

An index robot 120 is provided in the index frame 14. A guide rail 140, the lengthwise direction of which is parallel to the second direction 94, is provided in the index frame 14. The index robot 120 is movable on the guide rail 140. The index robot 120 includes hands 122 on which the substrates W are placed. The hands 122 are movable forward and backward, rotatable about an axis facing in the third direction 96, and movable along the third direction 96. The hands 122 may be spaced apart from each other in the vertical direction. The hands 122 may independently move forward and backward.

The process module 20 includes a buffer unit 200, a transfer chamber 300, and liquid treatment chambers 400. The buffer unit 200 provides a space in which the substrates W loaded into the process module 20 and the substrates W to be unloaded from the process module 20 temporarily stay. Each of the liquid treatment chambers 400 performs liquid treatment on the substrate W by dispensing a liquid onto the substrate W. The transfer chamber 300 transfers the substrates W between the buffer unit 200 and the liquid treatment chambers 400.

The transfer chamber 300 may be disposed such that the lengthwise direction thereof is parallel to the first direction 92. The buffer unit 200 may be disposed between the index module 10 and the transfer chamber 300. The liquid treatment chambers 400 may be disposed on opposite sides of the transfer chamber 300. The liquid treatment chambers 400 and the transfer chamber 300 may be disposed along the second direction 94. The buffer unit 200 may be located at one end of the transfer chamber 300.

According to an embodiment, on one side of the transfer chamber 300, the liquid treatment chambers 400 may be arranged in an A×B array (A and B being natural numbers of 1 or larger) along the first direction 92 and the third direction 96.

The transfer chamber 300 has a transfer robot 320. A guide rail 340, the lengthwise direction of which is parallel to the first direction 92, may be provided in the transfer chamber 300, and the transfer robot 320 is movable along the guide rail 340. The transfer robot 320 includes hands 322 on which the substrates W are placed. The hands 322 are movable forward and backward, rotatable about an axis facing in the third direction 96, and movable along the third direction 96. The hands 322 may be spaced apart from each other in the vertical direction. The hands 322 may independently move forward and backward.

The buffer unit 200 includes a plurality of buffers 220 in which the substrates W are placed. The buffers 220 may be spaced apart from each other along the third direction 96. A front face and a rear face of the buffer unit 200 are open. The front face is a face that faces the index module 10, and the rear face is a face that faces the transfer chamber 300. The index robot 120 may approach the buffer unit 200 through the front face, and the transfer robot 320 may approach the buffer unit 200 through the rear face.

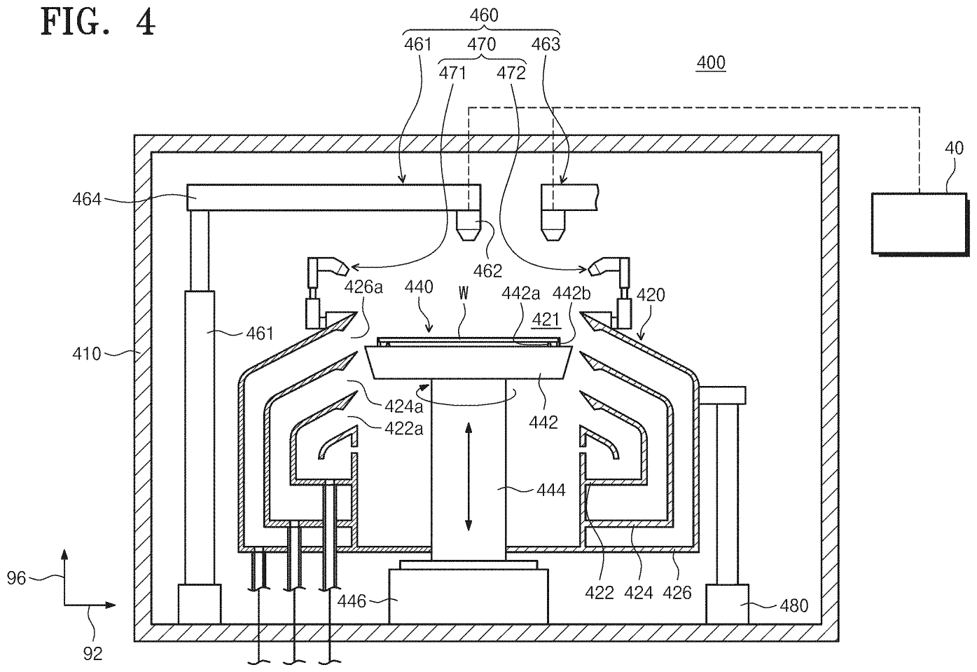

FIG. 4 is a schematic view illustrating one embodiment of the liquid treatment chambers 400 of FIG. 3. Referring to FIG. 4, the liquid treatment chamber 400 may have a housing 410, a cup 420, a support unit 440, a liquid dispensing unit 460, and a lifting unit 480.

The housing 410 has a substantially rectangular parallelepiped shape. The cup 420, the support unit 440, and the liquid dispensing unit 460 are disposed in the housing 410.

The cup 420 has a processing space that is open at the top, and a substrate W is processed with liquids in the processing space. The support unit 440 supports the substrate W in the processing space. The liquid dispensing unit 460 dispenses the liquids onto the substrate W supported on the support unit 440. The liquids may be sequentially dispensed onto the substrate W. The lifting unit 480 adjusts the relative height between the cup 420 and the support unit 440.

According to an embodiment, the cup 420 has a plurality of recovery bowls 422, 424, and 426. The recovery bowls 422, 424, and 426 have recovery spaces for recovering the liquids used to process the substrate W. The recovery bowls 422, 424, and 426 have a ring shape that surrounds the support unit 440. The treatment liquids scattered by rotation of the substrate W during a liquid treatment process may be introduced into the recovery spaces through inlets 422a, 424a, and 426a of the respective recovery bowls 422, 424, and 426.

According to an embodiment, the cup 420 has the first recovery bowl 422, the second recovery bowl 424, and the third recovery bowl 426. The first recovery bowl 422 is disposed to surround the support unit 440, the second recovery bowl 424 is disposed to surround the first recovery bowl 422, and the third recovery bowl 426 is disposed to surround the second recovery bowl 424. The second inlet 424a through which a liquid is introduced into the second recovery bowl 424 may be located in a higher position than the first inlet 422a through which a liquid is introduced into the first recovery bowl 422, and the third inlet 426a through which a liquid is introduced into the third recovery bowl 426 may be located in a higher position than the second inlet 424a.

The support unit 440 has a support plate 442 and a drive shaft 444. An upper surface of the support plate 442 may have a substantially circular shape and may have a larger diameter than the substrate W. Support pins 442a are provided on a central portion of the support plate 442 to support the rear surface of the substrate W. The support pins 442a protrude upward from the support plate 442 to space the substrate W apart from the support plate 442 by a predetermined distance.

Chuck pins 442b are provided on an edge portion of the support plate 442. The chuck pins 442b protrude upward from the support plate 442 and support the side of the substrate W to prevent the substrate W from escaping from the support unit 440 when rotated. The drive shaft 444 is driven by an actuator 446. The drive shaft 444 is connected to the center of a bottom surface of the support plate 442 and rotates the support plate 442 about the central axis thereof.

The lifting unit 480 moves the cup 420 in the vertical direction. The relative height between the cup 420 and the substrate W is changed by the vertical movement of the cup 420. Accordingly, the recovery bowls 422, 424, and 426 for recovering the treatment liquids may be changed depending on the types of liquids dispensed onto the substrate W, and thus the liquids may be separately recovered. Alternatively, the cup 420 may be fixed, and the lifting unit 480 may move the support unit 440 in the vertical direction.

The liquid dispensing unit 460 dispenses various types of treatment liquids onto the substrate W. The liquid dispensing unit 460 has a chemical dispensing member 461, an organic solvent dispensing member 463, and a cleaning solution dispensing member 470. The chemical dispensing member 461 dispenses a chemical onto the substrate W to remove a thin film or particles remaining on the substrate W. The chemical may be a liquid having a property of acid or base. For example, the chemical may include diluted sulfuric acid (H₂SO₄), phosphoric acid (P₂O₅), hydrofluoric acid (HF), and ammonium hydroxide (NH₄OH).

The chemical dispensing member 461 has a chemical nozzle 462, a support arm 464, and an arm actuator (not illustrated). In the drawing, the chemical dispensing member 461 includes the single chemical nozzle 462. However, in another embodiment, the chemical dispensing member 461 may include a plurality of chemical nozzles, and chemicals may be dispensed onto the substrate W through the different nozzles. The plurality of chemical nozzles may be supported by different arms, and the arms may be independently driven.

The cleaning solution dispensing member 470 dispenses a cleaning solution onto the substrate W to remove the chemical on the substrate W. Alternatively, when a nozzle having dispensed a liquid moves from a process position to a standby position and then a nozzle for dispensing another liquid moves from a standby position to a process position, nozzles 471 and 472 fixed to the cup 420 dispense deionized water onto the substrate W to prevent the substrate W from being naturally dried.

The cleaning solution dispensing member 470 includes the first nozzle 471 and the second nozzle 472. In an embodiment, the first nozzle 471 and the second nozzle 472 are fixed to the cup 420. The cleaning solution may be a liquid for removing a thin film or foreign matter remaining on the substrate W. For example, the cleaning solution may be deionized water.

The organic solvent dispensing member 463 dispenses an organic solvent, the surface tension of which is lower than that of the cleaning solution, onto the substrate W to replace the cleaning solution on the substrate W with the organic solvent. Likewise to the chemical dispensing member 461, the organic solvent dispensing member 463 has a solvent dispensing nozzle, a support arm, and an arm actuator that are not illustrated in the drawing. In an embodiment, the organic solvent may be isopropyl alcohol (IPA).

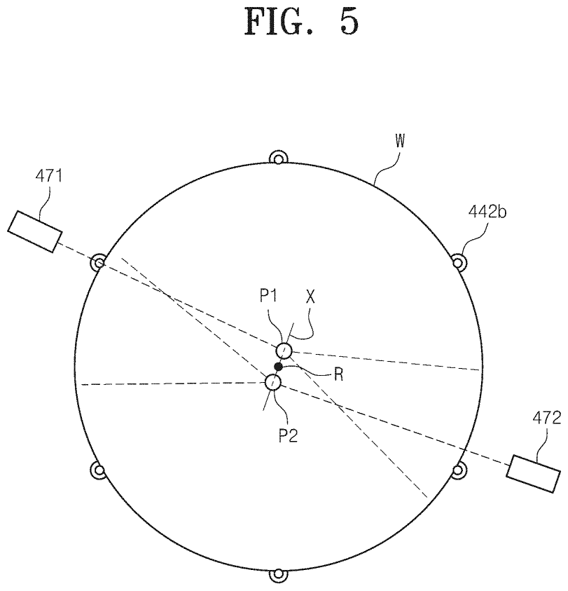

FIG. 5 is a top view illustrating the first nozzle 471 and the second nozzle 472 according to an embodiment of the inventive concept. Referring to FIG. 5, the first nozzle 471 and the second nozzle 472 dispense a first liquid and a second liquid in opposite directions toward each other. Here, the opposite directions may include a direction in which the first nozzle 471 faces toward the vicinity of the second nozzle 472 and a direction in which the second nozzle 472 faces toward the vicinity of the first nozzle 471, as well as directions in which the first nozzle 471 and the second nozzle 472 exactly face each other.

The first nozzle 471 dispenses the first liquid to a first point P1 on a target surface of the substrate W supported on the support unit 440. The second nozzle 472 dispenses the second liquid to a second point P2 on the target surface of the substrate W supported on the support unit 440.

When viewed from above, the first point P1 is located on one side of a virtual line X, and the second point P2 is located on an opposite side of the virtual line X. Here, the virtual line X is a straight line that connects a dispensing end of the first nozzle 471 and a dispensing end of the second nozzle 472 when viewed from above.

The first nozzle 471 dispenses the first liquid to the first point P1 spaced apart from the center R of the substrate W by a first distance. The second nozzle 472 dispenses the second liquid to the second point P2 spaced apart from the center R of the substrate W by a second distance in a direction away from the first point P1 with respect to the center R of the substrate W.

The center R of the substrate W is located between the first point P1 and the second point P2. In an embodiment, the distance between the first point P1 and the center R of the substrate W is equal to the distance between the second point P2 and the center R of the substrate W. The first point P1, the center R of the substrate W, and the second point P2 may be sequentially located on a straight line. The first liquid and the second liquid may be the same as each other. In an embodiment, the first liquid and the second liquid may be water.

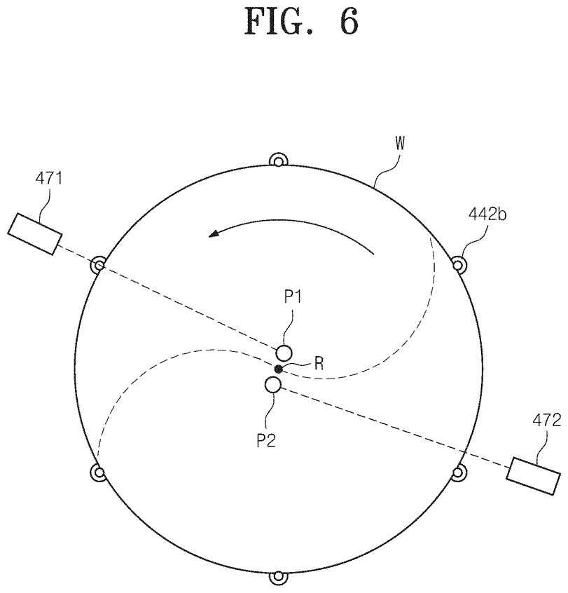

FIG. 6 illustrates a state in which the first nozzle 471 and the second nozzle 472 dispense the first liquid and the second liquid onto the substrate W in a cleaning step according to an embodiment of the inventive concept. Referring to FIG. 6, in the cleaning step, the first nozzle 471 and the second nozzle 472 dispense water in oblique directions from above the rotating substrate W.

The water is simultaneously dispensed from the first nozzle 471 and the second nozzle 472. The time during which the first nozzle 471 dispenses the water may completely overlap the time during which the second nozzle 472 dispenses the water. The first nozzle 471 dispenses the water to the first point P1 spaced apart from the center R of the substrate W in a first direction. The second nozzle 472 dispenses the water to the second point P2 spaced apart from the center R of the substrate W in a second direction.

The directions in which the water is dispensed from the first nozzle 471 and the second nozzle 472 differ from each other. Accordingly, the water dispensed from the first nozzle 471 and the water dispensed from the second nozzle 472 may be spread in different directions by the rotation of the substrate W.

When viewed from above, the water dispensed from the first nozzle 471 flows in a direction toward the second nozzle 472 by the rotation of the substrate W after dispensed onto the substrate W, and the water dispensed from the second nozzle 472 flows in a direction toward the first nozzle 471 by the rotation of the substrate W after dispensed onto the substrate W.

The first point P1 and the second point P2 may prevent or minimize collision between the first liquid and the second liquid when the first liquid and the second liquid dispensed onto the substrate W are spread by the rotation of the substrate W.

For example, in a case where the substrate W is a wafer having a diameter of 300 mm, the first point P1, the center R of the substrate W, and the second point P2 may be located on a straight line, and the distance between the first point P1 and the center R of the substrate W and the distance between the second point P2 and the center R of the substrate W may be 5 mm.

Next, an example of a method for processing a substrate using the substrate processing apparatus of FIG. 4 will be described.

The substrate processing method includes a liquid treatment step, a cleaning step, a solvent dispensing step, and a drying step. To perform the substrate processing method that will be described below, a controller 40 controls the liquid dispensing unit 460 and the cleaning solution dispensing member 470.

In the liquid treatment step, the liquid dispensing unit 460 dispenses a chemical onto the rotating substrate W to process the substrate W. Thereafter, the dispensing of the chemical is stopped, and the cleaning step is performed. In the cleaning step, the dispensing of the chemical is stopped, and the first nozzle 471 and the second nozzle 472 dispense a cleaning solution onto the rotating substrate W. When the cleaning step is completed, the solvent dispensing step is performed. In the solvent dispensing step, the cleaning solution on the substrate W is replaced with an organic solvent. When the solvent dispensing step is completed, the drying step is performed to dry the substrate W. The substrate W may be dried while being rotated at high speed. Selectively, in the drying step, while the substrate W is rotated, a drying gas such as an inert gas may be dispensed onto the substrate W. The drying gas may be dispensed in a heated state. Selectively, a chamber that performs the drying process in the drying step may dry the substrate W using a supercritical fluid.

In the above-described embodiment, the cleaning solution dispensing member 470 has been described as including the first nozzle 471 and the second nozzle 472. However, the cleaning solution dispensing member 470 may include three or more nozzles.

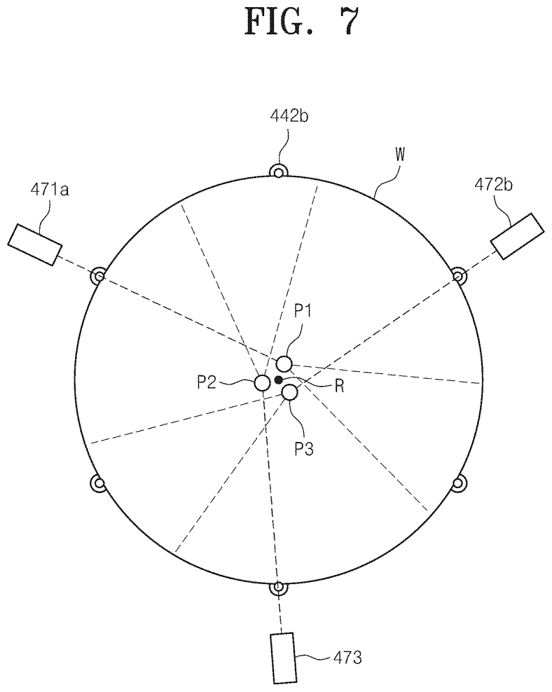

FIG. 7 is a schematic view illustrating an example that the cleaning solution dispensing member 470 includes a first nozzle 471a, a second nozzle 472a, and a third nozzle 473. Referring to FIG. 7, the cleaning solution dispensing member 470 may further include the third nozzle 473 that dispenses a third liquid onto the substrate W in an oblique direction from above the rotating substrate W. A first liquid dispensed from the first nozzle 471a may be directed between the second nozzle 472a and the third nozzle 473, and a second liquid dispensed from the second nozzle 472a may be directed between the first nozzle 471a and the third nozzle 473.

According to the embodiments of the inventive concept, water is dispensed onto the substrate W from the opposite sides to wet the substrate W. Accordingly, a section in which collision of the water dispensed onto the substrate W occurs may be minimized, and scattering of the water may be minimized. In addition, a phenomenon in which the water collides with the chuck pins 442b in the edge region of the substrate W and scatters outside the substrate W may be prevented.

According to the embodiments of the inventive concept, the first point P1 to which water is dispensed from the first nozzle 471 is spaced apart from the second point P2 to which water is dispensed from the second nozzle 472. Accordingly, even when the water is simultaneously dispensed from the first nozzle 471 and the second nozzle 472, the water level on the substrate W may be prevented from being rapidly raised.

Although it has been exemplified that the time during which the first nozzle 471 dispenses the water completely overlaps the time during which the second nozzle 472 dispenses the water, the time during which the first nozzle 471 dispenses the water may partly overlap the time during which the second nozzle 472 dispenses the water.

Although it has been described that the first nozzle 471 and the second nozzle 472 are fixed to the cup 420, the first nozzle 471 and the second nozzle 472 may be fixed to another part rather than the cup 420.

Although it has been described that the cleaning solution dispensing member 470 includes the first nozzle 471 and the second nozzle 472 fixed to the cup 420, the cleaning solution dispensing member 470 may further include a nozzle that is mounted on a movable arm and that dispenses a cleaning solution, in addition to the first nozzle 471 and the second nozzle 472.

Although it has been described that the first nozzle 471 and the second nozzle 472 dispense the cleaning solution such as water, the spirit of the inventive concept may be applied to dispensing various liquids of different types other than water.

As described above, according to the embodiments of the inventive concept, the substrate processing apparatus and method may improve efficiency in processing a substrate.

According to the embodiments of the inventive concept, the substrate processing apparatus and method may prevent collision of deionized water dispensed to different positions on a substrate.

According to the embodiments of the inventive concept, the substrate processing apparatus and method may prevent a chamber or parts therein from being contaminated by a cleaning solution dispensed onto a substrate.

Effects of the inventive concept are not limited to the above-described effects, and any other effects not mentioned herein may be clearly understood from this specification and the accompanying drawings by those skilled in the art to which the inventive concept pertains.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1.-6. (canceled)

7. An apparatus for processing a substrate, the apparatus comprising:
a housing having a processing space therein;
a support unit configured to support the substrate in the processing space;
a first nozzle configured to dispense a first liquid to a first point on a target surface of the substrate supported on the support unit; and
a second nozzle configured to dispense a second liquid to a second point on the target surface of the substrate supported on the support unit,
wherein when viewed from above, the first point is located on one side of a virtual line connecting a dispensing end of the first nozzle and a dispensing end of the second nozzle, and
wherein the second point is located on an opposite side of the virtual line.

8. The apparatus of claim 7, wherein the center of the substrate is located between the first point and the second point.

9. The apparatus of claim 7, wherein a distance between the first point and the center of the substrate is equal to a distance between the second point and the center of the substrate.

10. The apparatus of claim 7, wherein when viewed from above, the first nozzle and the second nozzle are provided in opposite directions toward each other.

11. The apparatus of claim 7, wherein the first nozzle dispenses the first liquid to the first point spaced apart from the center of the substrate by a first distance, and
wherein the second nozzle dispenses the second liquid to the second point spaced apart from the center of the substrate by a second distance in a direction away from the first point with respect to the center of the substrate.

12. The apparatus of claim 11, wherein the first distance is equal to the second distance.

13. The apparatus of claim 7, further comprising:
a cup configured to surround the processing space,
wherein the first nozzle and the second nozzle are fixed to the cup.

14. The apparatus of claim 7, wherein the first liquid and the second liquid are the same as each other.

15.-20. (canceled)
